(19) United States
(12) Patent Application Publication
(10) Pub. No.: US 2010/0237406 A1
(43) Pub. Date: Sep. 23, 2010

(54) SEMICONDUCTOR MEMORY DEVICE AND MANUFACTURING METHOD THEREOF

(75) Inventor: KIYONORI OYU, TOKYO (JP)

Correspondence Address: YOUNG & THOMPSON, 209 Madison Street, Suite 500, Alexandria, VA, 22314, US

(73) Assignee: ELPIDA MEMORY INC., TOKYO (JP)

(21) Appl. No.: 12/724,599

(22) Filed: Mar. 16, 2010

(30) Foreign Application Priority Data
Mar. 17, 2009 (JP) 2009-064782

(51) Int. Cl. H01L 27/105

(52) U.S. Cl. 257/329; 257/E29.256; 257/E29.262; 257/E27.081

(57) ABSTRACT

A semiconductor memory device includes a silicon pillar that is provided with a first channel formed in a first area on one side among two sides that are perpendicular to an extension direction of a bit line, a second channel formed in a second area on the other side among the two sides that is not overlapped with the first area in the extension direction of the bit line, and of which the other area on the two sides is an insulating oxide film formed by being oxidized, and two word lines that cover the one side and the other side of the silicon pillar via a gate insulating film, respectively. The first channel and the second channel are separated from each other in an insulating manner by the insulating oxide film.

### FIELD OF THE INVENTION

The present invention relates to a semiconductor memory device and a manufacturing method thereof, and more particularly relates to a semiconductor memory device including a vertical transistor using a silicon pillar and a method of manufacturing the semiconductor memory device.

### DESCRIPTION OF RELATED ART

In recent years, the integration enhancement of semiconductor memory devices has been mainly achieved by downscaling the transistor size. However, the downscaling of the transistor size is coming close to its limit, and if the transistor size is reduced even more, it may cause a malfunction of the transistor due to a short channel effect or the like.

As a measure to fundamentally solve such a problem, a method of forming transistors in a three-dimensional manner by three-dimensionally processing a semiconductor substrate has been proposed. In particular, a three-dimensional transistor that uses a silicon pillar that extends in a vertical direction with respect to a main plane of the semiconductor substrate as a channel has an advantage in that its occupation area is small, a large drain current can be obtained by a complete depletion, and it is possible to realize the close-packed layout of 4F² (where F is the minimum feature size) (see Japanese Patent Application Laid-open Nos. 2008-288391, 2008-300623, 2008-311641, and 2009-010366).

As a structure of a three-dimensional transistor for realizing the layout of 4F², an SGT (Surrounding Gate Transistor) structure is commonly used at present. In the SGT structure, a single silicon pillar functions as a single transistor.

However, an even denser layout than the layout of 4F² has been demanded in recent years, and to satisfy the demand, a case of realizing a layout of 2F² has been considered by making a single silicon pillar function as two transistors. In this case, among two sides of the silicon pillar, which is perpendicular to a column direction, a first channel is provided on one side and a second channel is provided on the other side, and a word line is wired corresponding to each of the channels.

However, in the case of causing a single silicon pillar to function as two transistors in the above-described manner, a mutual interference occurs between the channels. For example, if a second channel is switched ON and OFF when a first channel is in an OFF state, a sub-threshold current flowing through the first channel is changed, and in some cases, there can be a loss of accumulated charges from a capacitor that is connected to the first channel. This means that the data holding characteristic of a memory cell is degraded.

### SUMMARY

In one embodiment, there is provided a semiconductor memory device comprising: a silicon pillar including a first side surface perpendicular to an extension direction of a bit line, a second side surface parallel to the first side surface, a first channel region positioned on the first side surface, a second channel region positioned on the second side surface, and an oxide region that electrically isolates the first and second channel regions; and first and second word lines that cover the first and second side surfaces via gate insulating films, respectively, wherein the first and second channel regions being not overlapped in the extension direction of the bit line.

In another embodiment, there is provided a semiconductor memory device comprising a silicon pillar of a rectangular cube made of silicon and insulator, wherein the silicon pillar includes first and second channel regions that serve as channels of first and second vertical MOS transistors having a common lower diffusion layer, respectively, the first and second channel regions are provided at diagonal positions of the silicon pillar, and the first channel region and the second channel region are electrically isolated from each other by the insulator in the silicon pillar.

In still another embodiment, there is provided a method of manufacturing a semiconductor memory device, comprising: forming a silicon pillar of which a planar shape is rectangular with its longitudinal direction parallel to an extension direction of a word line; forming a silicon nitride film that covers first and second areas of the silicon pillar without covering other area, the first area being positioned on one side among two sides parallel to the extension direction of the word line, the second area being positioned on other side among the two sides, the first and second areas being not overlapped in an extension direction of the bit line that is perpendicular to the extension direction of the word line; and forming an insulating oxide film in the silicon pillar by thermally oxidizing the silicon pillar so as to remain nonoxide areas provided at an inner side of the first area and at an inner side of the second area, the nonoxide areas being electrically isolated from each other by the insulating oxide film.

According to the present invention, because the first channel and the second channel are separated from each other by an insulating oxide film, there is no mutual interference between the channels. In addition, because two channels are provided in a single silicon pillar by being staggered in a row direction, it is possible to realize at least a layout of 3F².

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plan view of a semiconductor memory device according to an embodiment of the present invention;

FIG. 1B is an enlarged view of an area A shown in FIG. 1A;

FIG. 2 is a cross section of the semiconductor memory device cut along a line B-B′ shown in FIG. 1A;

FIG. 3 is a cross section of the semiconductor memory device cut along a line C-C′ shown in FIG. 1A;

FIGS. 4, 6, 8, 11, 14, 17, 20, 23, 26, 29, 32, 35, 38, 41, and 44 are plan views showing a manufacturing method of the semiconductor memory device according to an embodiment of the present invention;

FIGS. 5, 7, 9, 12, 15, 18, 21, 24, 27, 30, 33, 36, 39, 42, and 45 are cross sections showing a manufacturing method of the semiconductor memory device according to an embodiment of the present invention and corresponding to a line B-B′ shown in FIG. 1A; and

FIGS. 10, 13, 16, 19, 22, 25, 28, 31, 34, 37, 40, 43, and 46 are cross sections showing a manufacturing method of the semiconductor memory device according to an embodiment of the present invention and corresponding to a line C-C′ shown in FIG. 1A.

### DETAILED DESCRIPTION OF THE PREFERRED EMBODIMENTS

Preferred embodiments of the present invention will now be explained in detail with reference to the drawings.

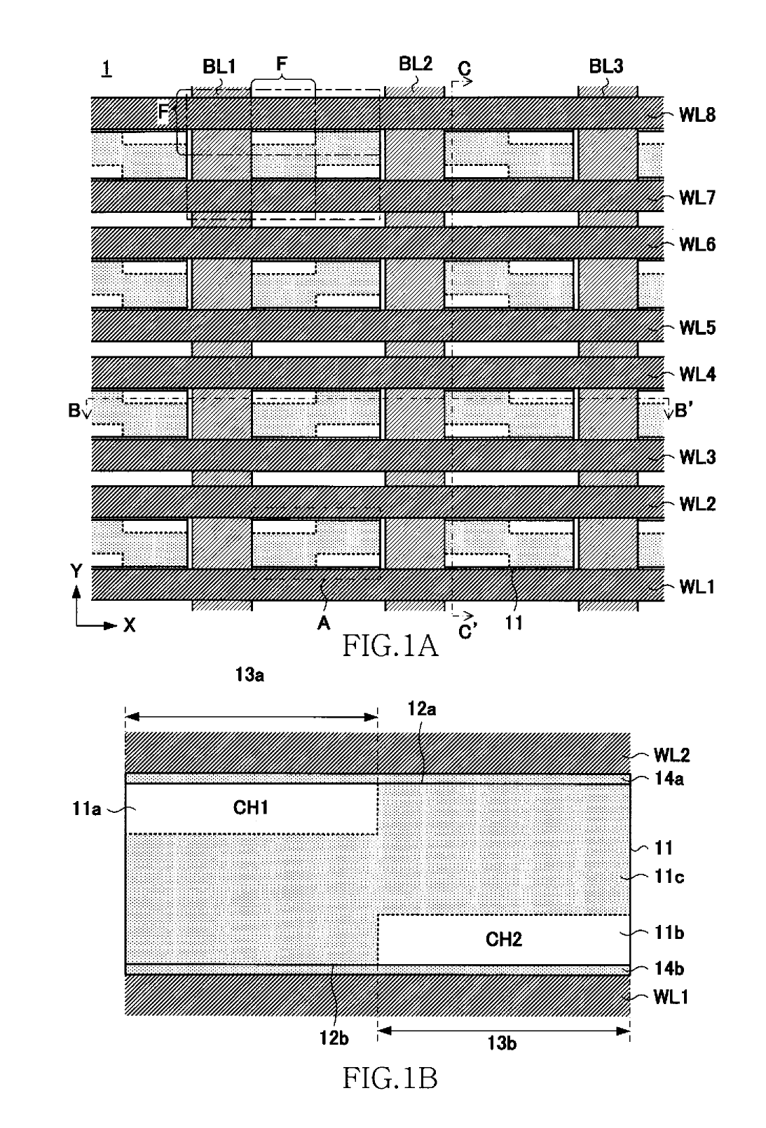

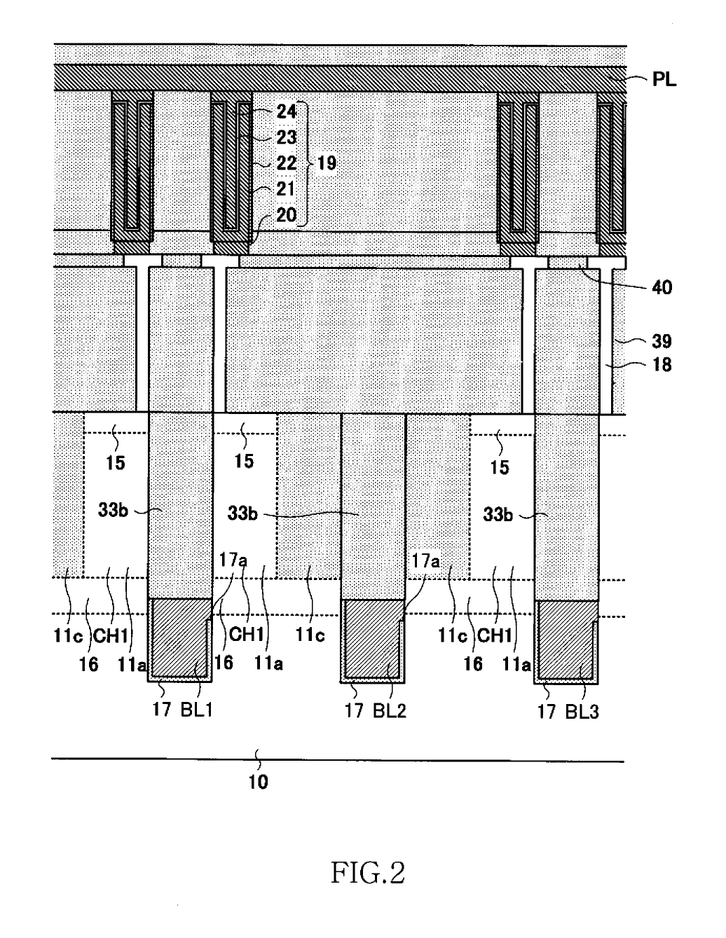

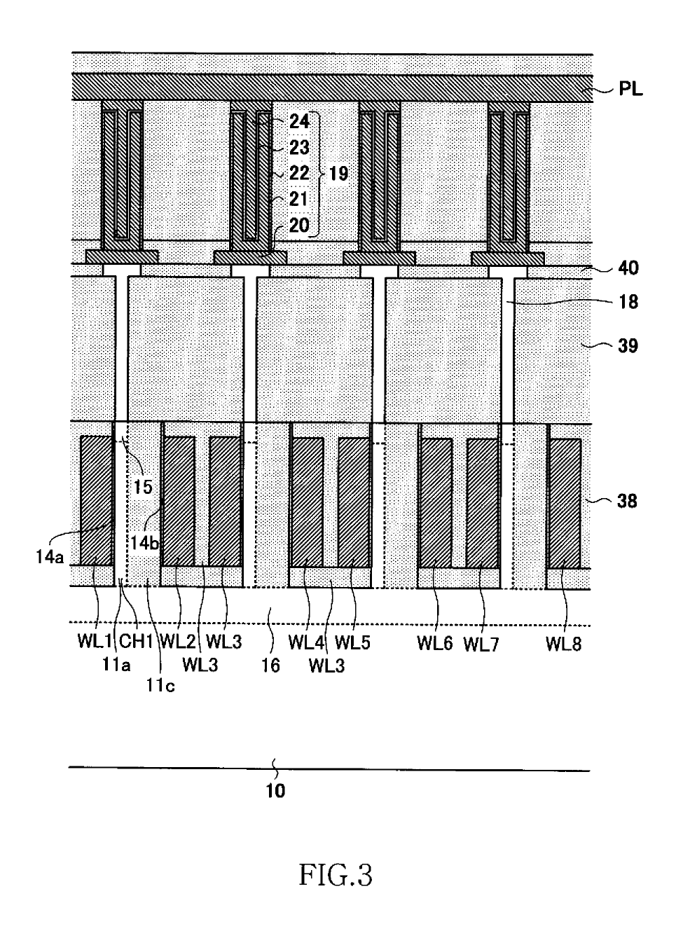

FIG. 1A is a plan view of a semiconductor memory device 1 according to an embodiment of the present invention. FIG. 1B is an enlarged view of an area A shown in FIG. 1A. FIG. 2 is a cross section of the semiconductor memory device 1 cut along a line B-B′ shown in FIG. 1A; and FIG. 3 is a cross section of the semiconductor memory device 1 cut along a line C-C′ shown in FIG. 1A. In FIGS. 1A and 1B, some of the constituent elements are omitted to clearly show the characteristic structure of the present invention. The omitted constituent elements are described in the subsequent drawings following FIG. 2.

As shown in the above drawings, the semiconductor memory device 1 has a structure in which a plurality of silicon pillars 11 is arranged in a matrix form on a P-type semiconductor substrate 10. Each of the silicon pillars 11 is a structure of a square pillar formed with silicon and insulator, with the length in an X direction about 2F and the length in a Y direction about a half of the length in the X direction. The intervals in the X direction and the Y direction (a distance between centers) of the silicon pillars 11 are 3F and 2F, respectively. Each of the silicon pillars functions as two cell transistors (vertical MOS transistors), as will be described later, and thus it is safe to say that the semiconductor memory device 1 realizes a layout of 3F².

A plurality of mutually intersecting word lines WL and bit lines BL are provided between the silicon pillars 11. The word lines WL extend along the X direction shown in FIG. 1A, and the bit lines BL extend along the Y direction shown in FIG. 1A.

The structure of each of the silicon pillars 11 is explained with reference to FIG. 1B. As shown in FIG. 1B, the silicon pillar 11 has a nonoxide area 11a on the inner side of a part (an area 13a) of a first side 12a among two sides that are perpendicular to the Y direction. The silicon pillar 11 also has a nonoxide area 11b on the inner side of a part (an area 13b) of a second side 12b that is opposite to the first side 12a, which is not overlapped with the area 13a in the Y direction. As shown in FIG. 1B, the nonoxide areas 11a and 11b are arranged at the diagonal positions of the silicon pillar 11, and it is preferable that the lengths of the nonoxide areas 11a and 11b in the X direction are set to the minimum feature size F.

An area (an area 11c) other than the nonoxide areas 11a and 11b of the silicon pillar 11 is oxidized, which is formed with an insulator made of silicon oxide (an insulating oxide film). The nonoxide areas 11a and 11b are separated from each other by insulation by the insulating area 11c.

Gate insulating films 14a and 14b are formed along the first and second sides 12a and 12b of the silicon pillar 11, respectively. The first and second sides 12a and 12b are covered byword lines WL2 and WL1 via the gate insulating films 14a and 14b, respectively. The word lines WL1 and WL2 are arranged opposite to each other across the silicon pillar 11.

As shown in FIG. 1A, in the semiconductor memory device 1, the silicon pillars 11 have an opposite structure in the X direction in every other column. Such a structure is adopted for convenience in the manufacturing process, which will be described later, so that all the structures of the silicon pillars 11 in the X direction can be set in the same manner.

As shown in FIGS. 2 and 3, an impurity diffusion layer 15 is formed in a top end of the nonoxide area 11a of the silicon pillar 11. Although it is not shown in the drawings, the impurity diffusion layer 15 is also formed in a top end of the nonoxide area 11b. Furthermore, an impurity diffusion layer 16 is formed in a ground silicon layer (the semiconductor substrate 10) of the silicon pillar 11. In the present embodiment, the impurity diffusion layer 16 is commonly provided for every column of the silicon pillars 11 as shown in FIG. 3; however, it can be provided in a separate manner for each of the silicon pillars 11.

The impurity diffusion layer 16 is electrically connected to one of the two adjacent bit lines BL. As shown in FIG. 2, each of the bit lines BL is covered by an insulating film 17 for separating it from the other structural elements in an insulating manner, while having an opening 17a at the top of one side in the X direction. The impurity diffusion layer 16 is electrically connected to the bit line BL via the opening 17a.

Each of the impurity diffusion layer 15 is connected to a memory element 19 via a memory element contact plug 18. The memory element 19 is provided for each of the impurity diffusion layer 15. FIGS. 2 and 3 show an example in which the semiconductor memory device 1 is a DRAM (Dynamic Random Access Memory). In this case, as shown in the drawings, the memory element 19 is configured with conductors 20 and 21 that constitute a lower electrode, an insulating film 22 that covers a side surface of the conductor 21, a capacitive insulating film 23, and a conductor 24 that works as an upper electrode. The conductor 24 is connected to a reference potential wiring PL. If the semiconductor memory device 1 is a memory device other than a DRAM, a memory element corresponding to the memory device is employed as the memory element 19. For example, when the semiconductor memory device 1 is a PRAM (Phase change Random Access Memory), a phase change film is used for the memory element 19.

With the above configuration, each of the silicon pillars 11 functions as two cell transistors. That is, for example, in the case of the silicon pillar 11 in the area A shown in FIGS. 1A and 1B, when the word line WL2 is activated, a channel CH1 (a first channel) having a channel width F is formed between the impurity diffusion layer 15 and the impurity diffusion layer 16 in the nonoxide area 11a. The bit line BL1 is connected to the memory element 19 corresponding to the impurity diffusion layer 15 in the nonoxide area 11a by the channel CH1, so that a read operation or a write operation can be performed with respect to the memory element 19 via the bit line BL1. On the other hand, when the word line WL1 is activated, a channel CH2 (a second channel) having a channel width F is formed between the impurity diffusion layer 15 and the impurity diffusion layer 16 in the nonoxide area 11b. The bit line BL1 is connected to the memory element 19 corresponding to the impurity diffusion layer 15 in the nonoxide area 11b by the channel CH2, so that a read operation or a write operation can be performed with respect to the memory element 19 via the bit line BL2.

As described above, in the semiconductor memory device 1, the channel CH1 (the first channel) and the channel CH2 (the second channel) are separated from each other in an insulating manner by the insulating area 11c, so that there is no mutual interference between the channels. Therefore, it is possible to prevent the degradation of the data holding characteristic of a memory cell due to the mutual interference between the channels.

In addition, by providing two channels in a single silicon pillar 11 in a staggered manner in a row direction, at least a layout of 3F² can be realized.

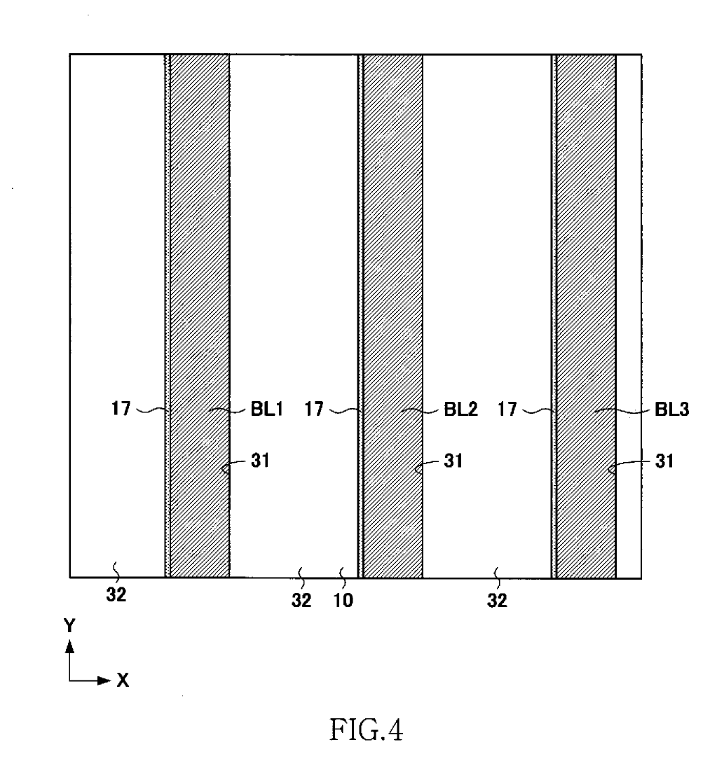

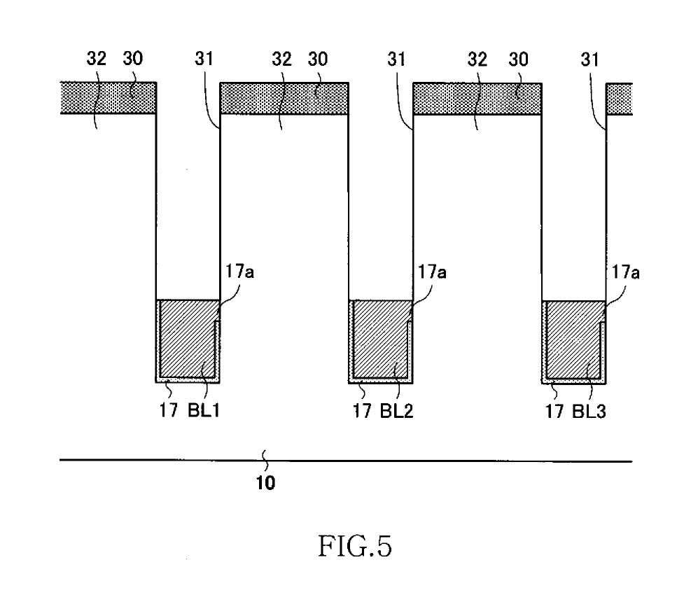

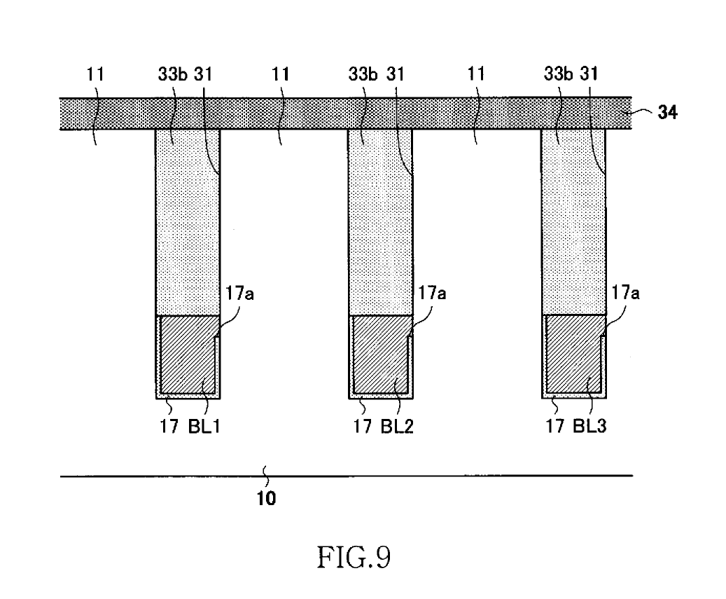

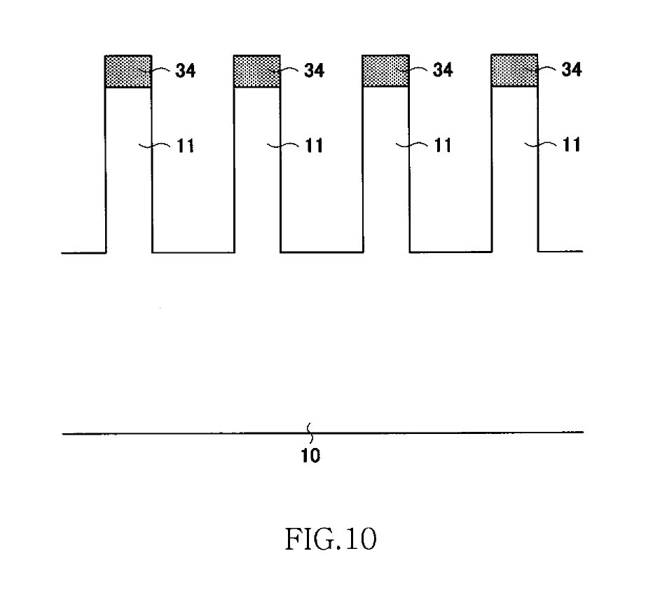

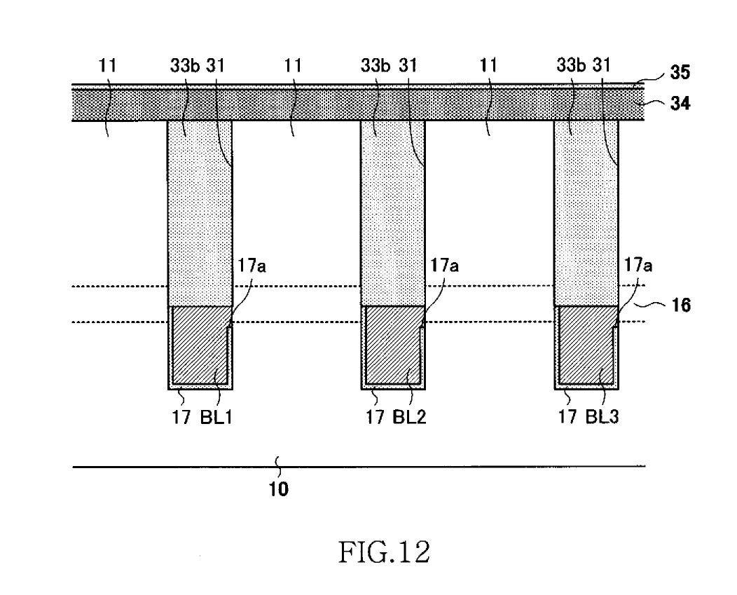

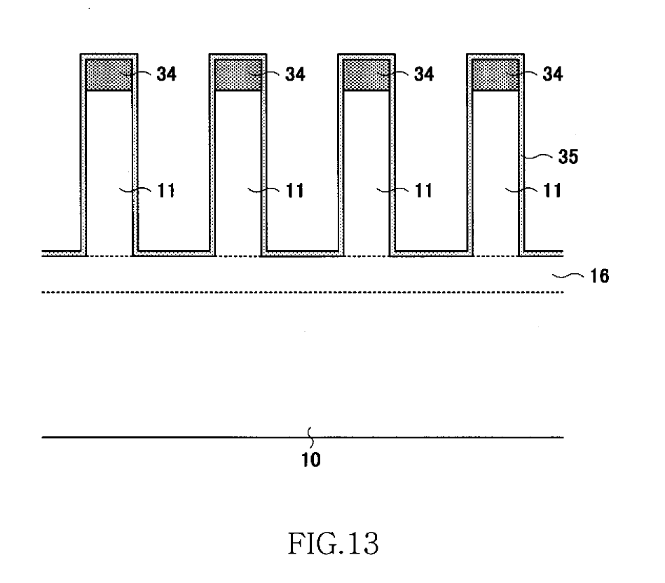

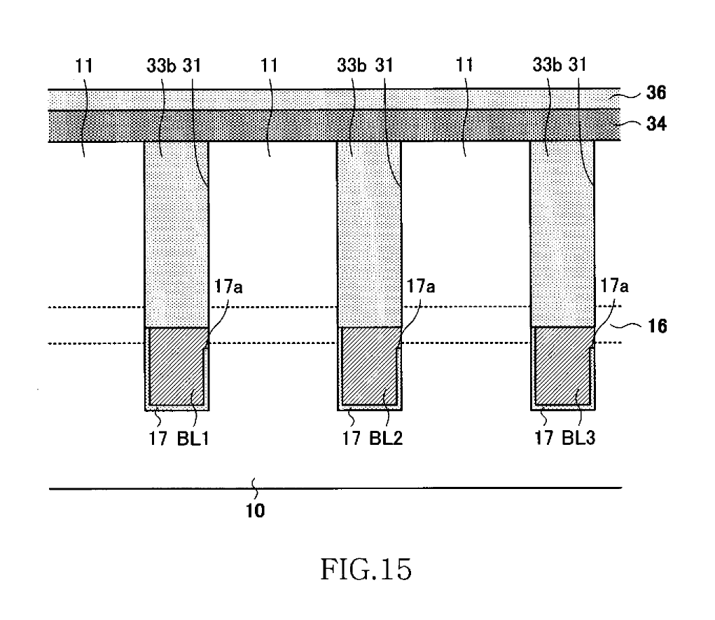

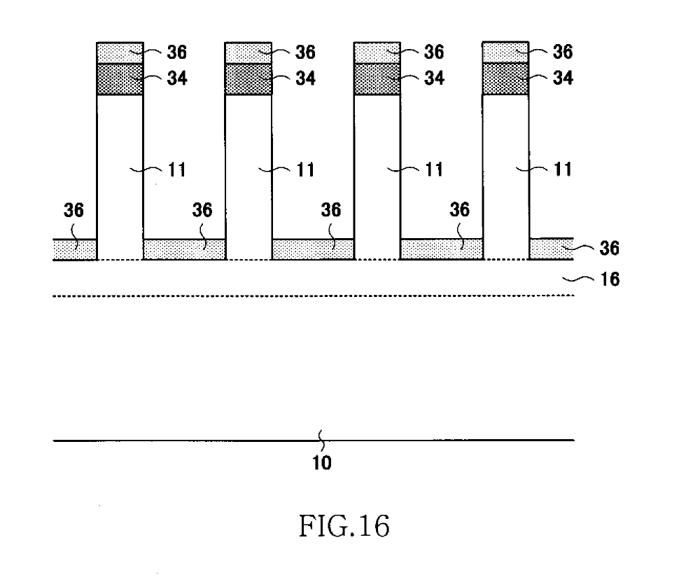

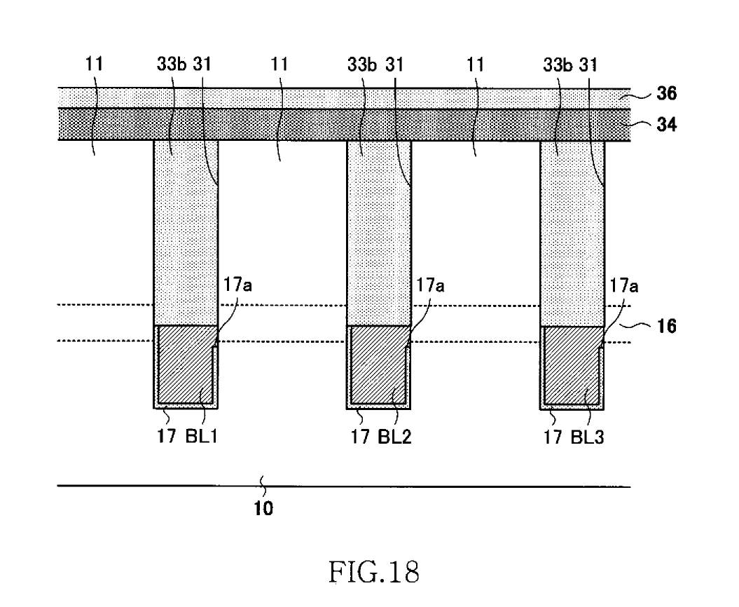

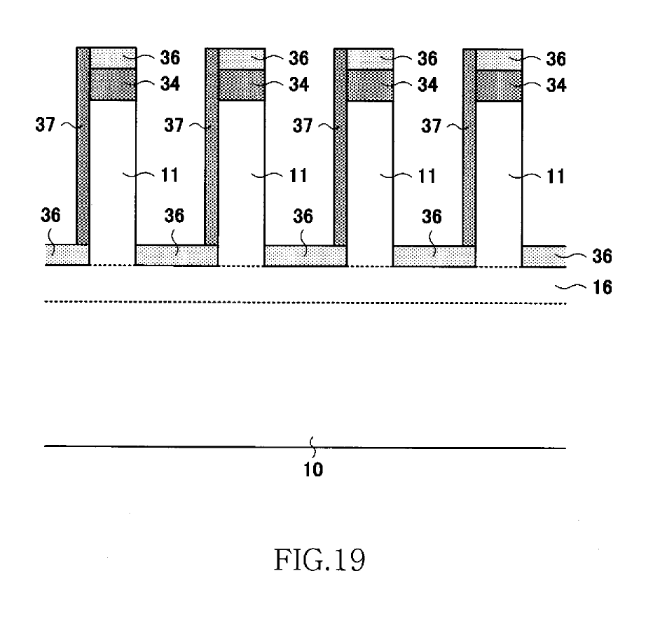

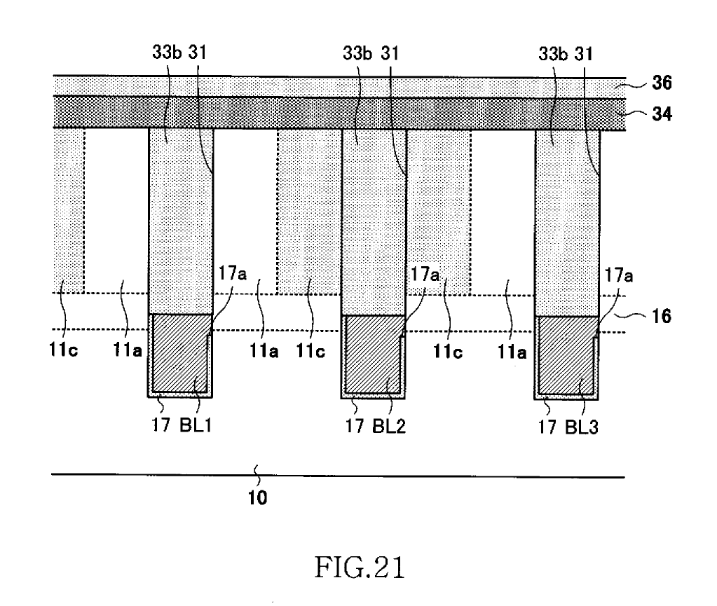

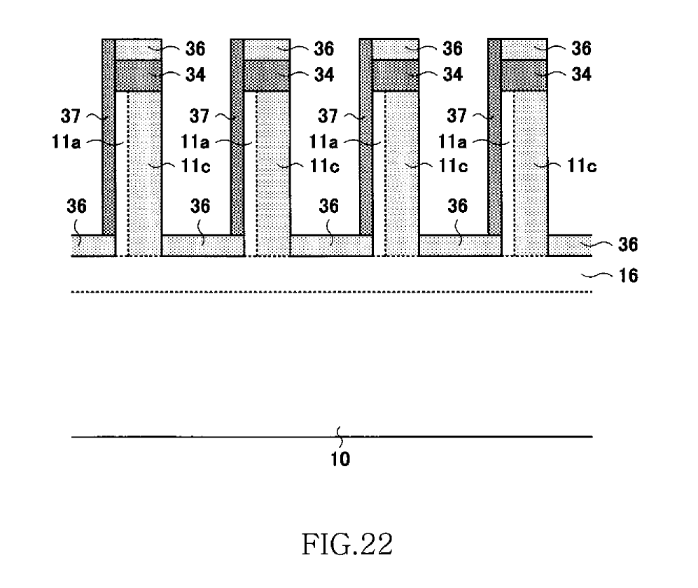

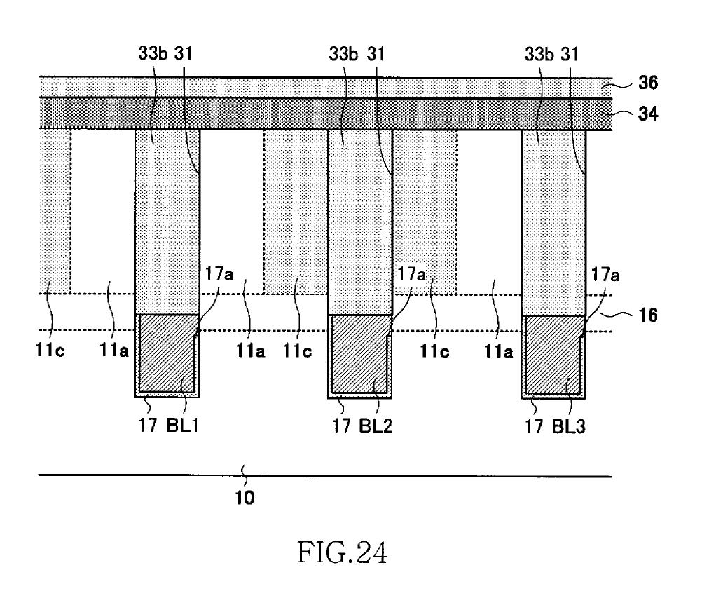

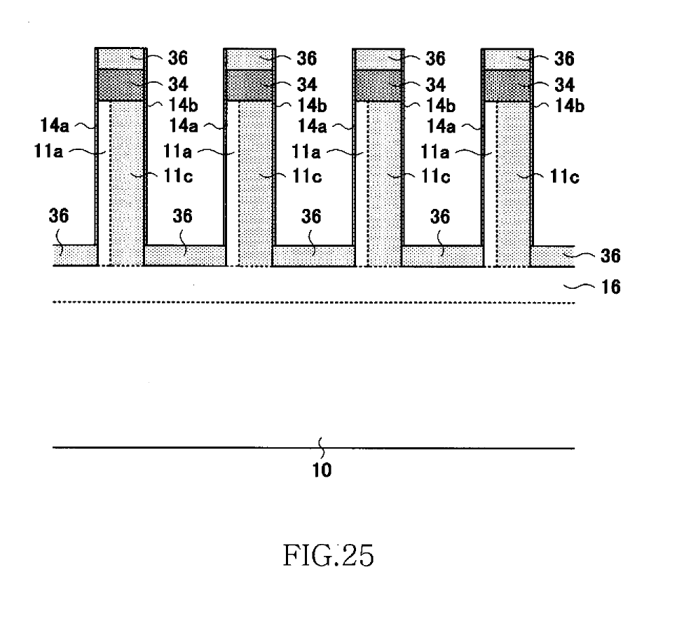

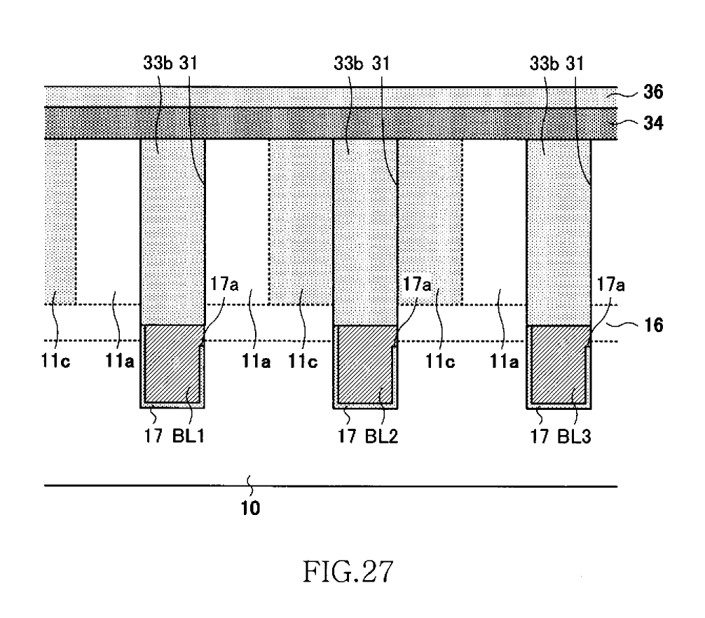

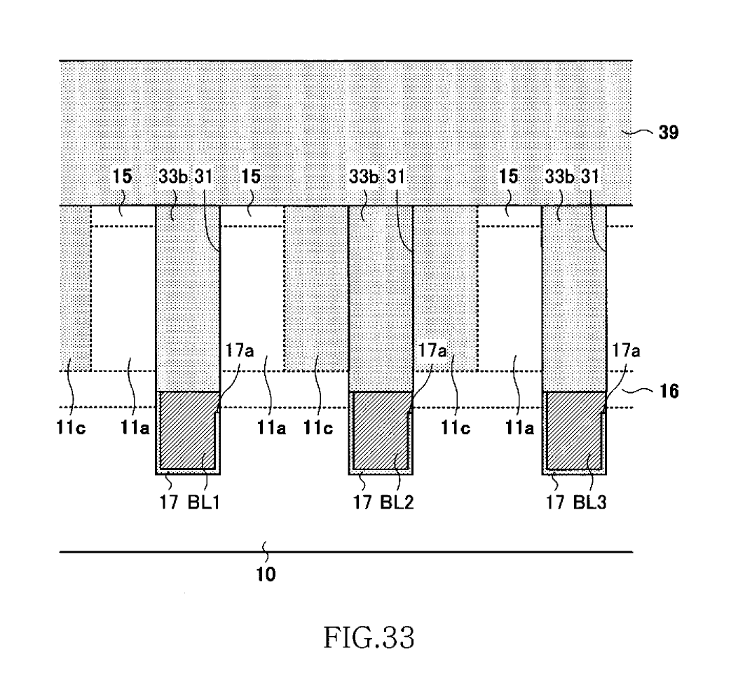

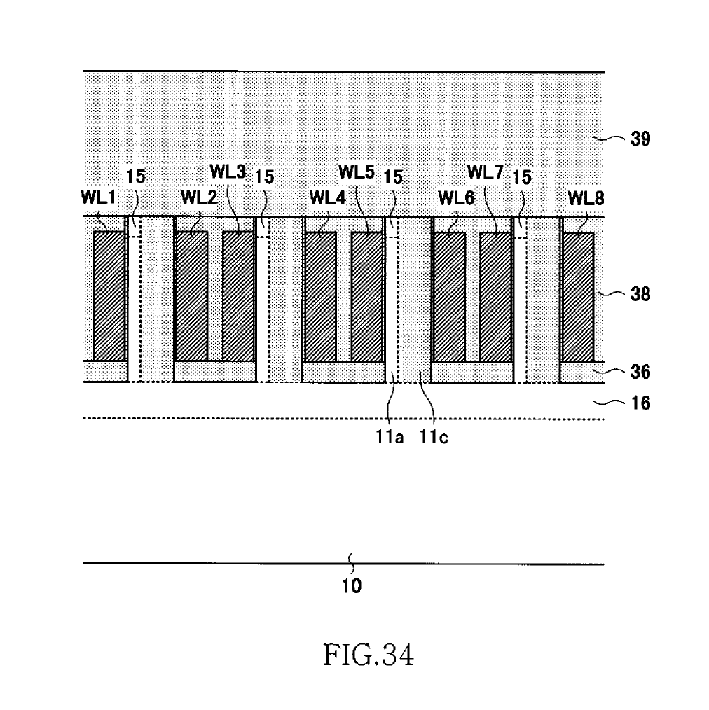

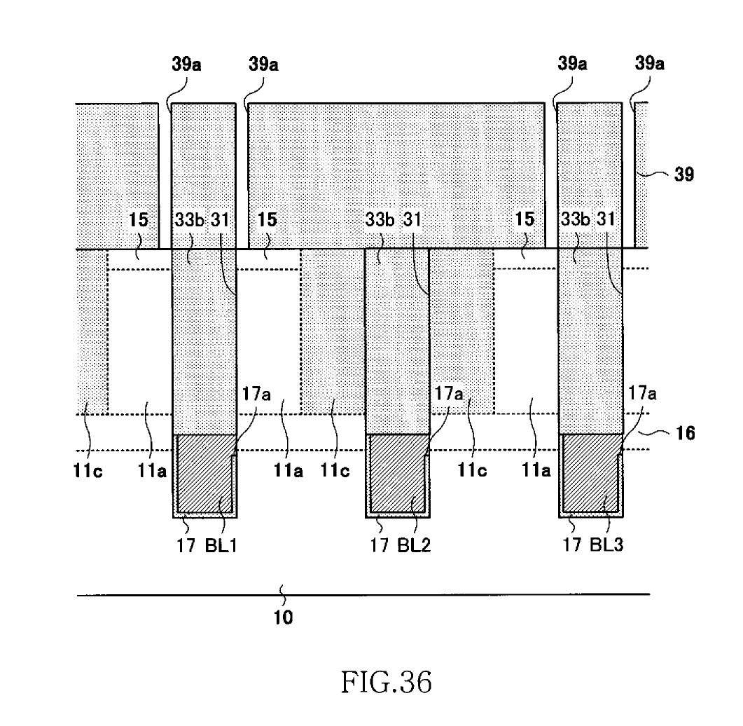

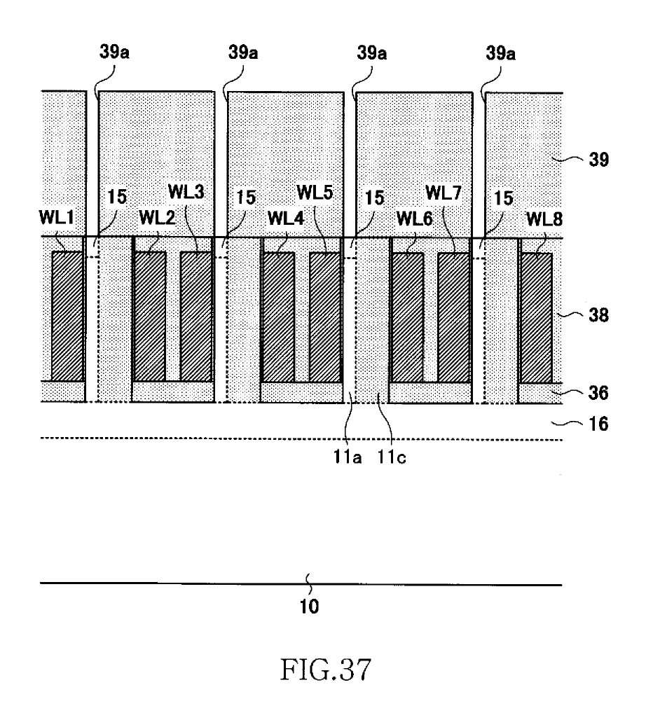

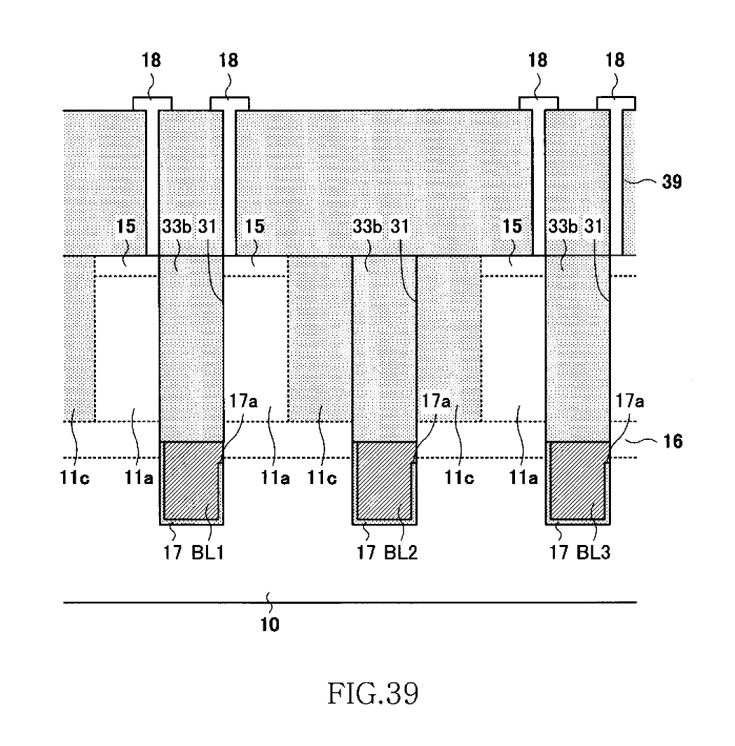

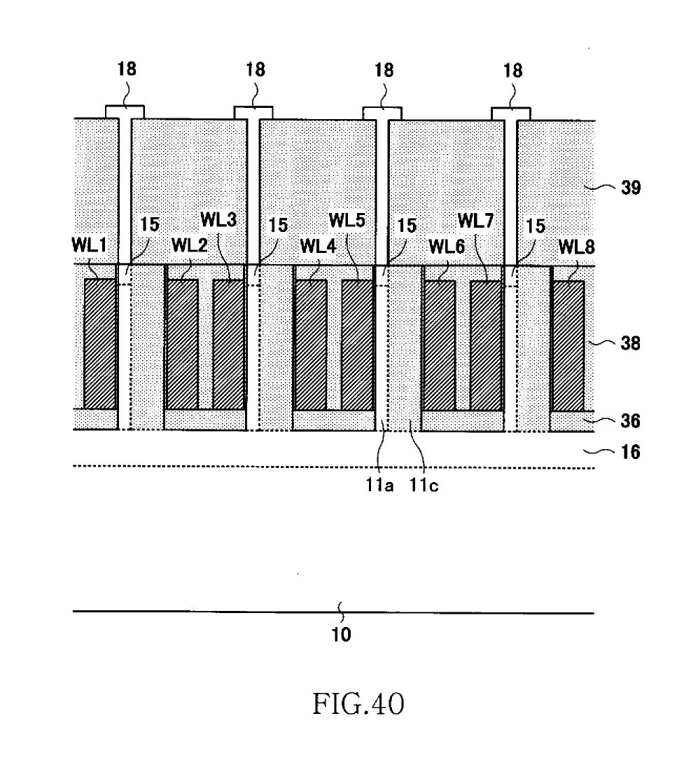

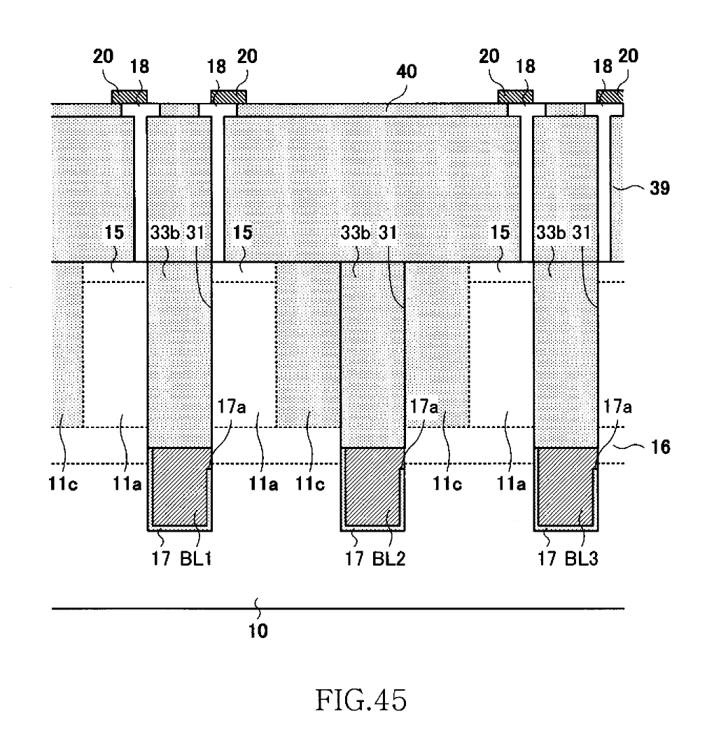

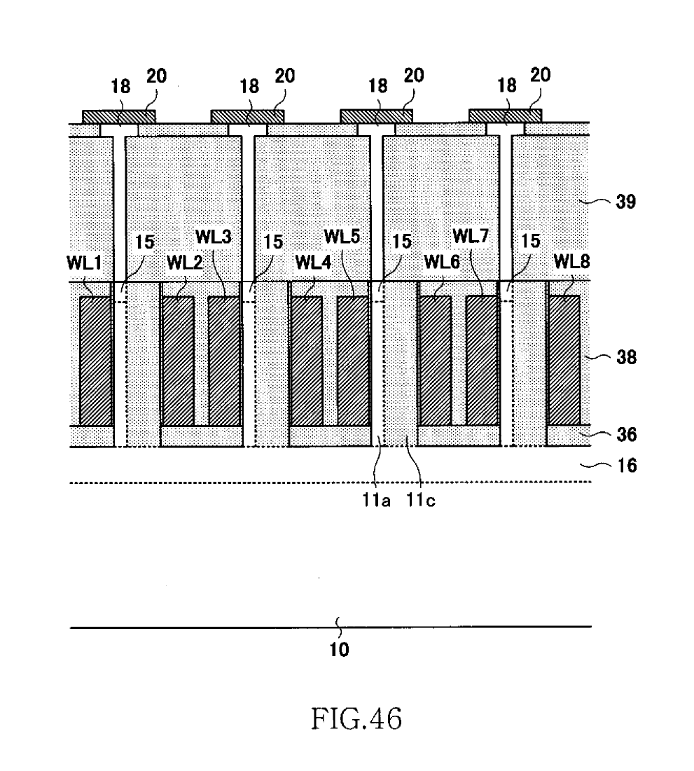

A manufacturing method of the semiconductor memory device 1 is explained next with reference to FIGS. 4 to 46. Among FIGS. 4 to 46, each of FIGS. 4, 6, 8, 11, 14, 17, 20, 23, 26, 29, 32, 35, 38, 41, and 44 is a plan view of the semiconductor memory device 1 corresponding to FIG. 1A, each of FIGS. 5, 7, 9, 12, 15, 18, 21, 24, 27, 30, 33, 36, 39, 42, and 45 is a cross section of the semiconductor memory device 1 corresponding to FIG. 2, and each of the remaining drawings is a cross section of the semiconductor memory device 1 corresponding to FIG. 3.

First, as shown in FIGS. 4 and 5, on a top surface of the semiconductor memory device 10, a mask pattern 30 of silicon nitride is formed and a groove 31 is formed with a depth of about 170 nm and a width of about F at a position corresponding to a bit line forming area by etching the semiconductor substrate 10 (excluding the area of the mask pattern 30). In FIG. 4, illustration of the mask pattern 30 is omitted. By forming the groove 31, the area other than the groove 31 is formed as a silicon beam 32 having a height of about 170 nm and a width of about 2F.

Next, as shown in FIGS. 4 and 5, an embedded bit line BL of which surfaces other than the top surface are covered by the insulating film 17 are formed on the bottom of the groove 31. At this time, a portion of the top of one side of the insulating film 17 in the X direction is removed to form the opening 17a. The top surface of the bit line BL is at a height of 50 nm from the bottom of the groove 31. As a material for the bit line BL, a conductive material is used, such as high concentration polysilicon (doped polysilicon in which a high concentration impurity is doped) or metal (such as a layered film of titan nitride and tungsten). In a case of using metal for the bit line BL, it is preferable to use polysilicon or silicide at the contact portion with the semiconductor substrate 10 (the portion of the opening 17a) to prevent contamination of the semiconductor substrate 10.

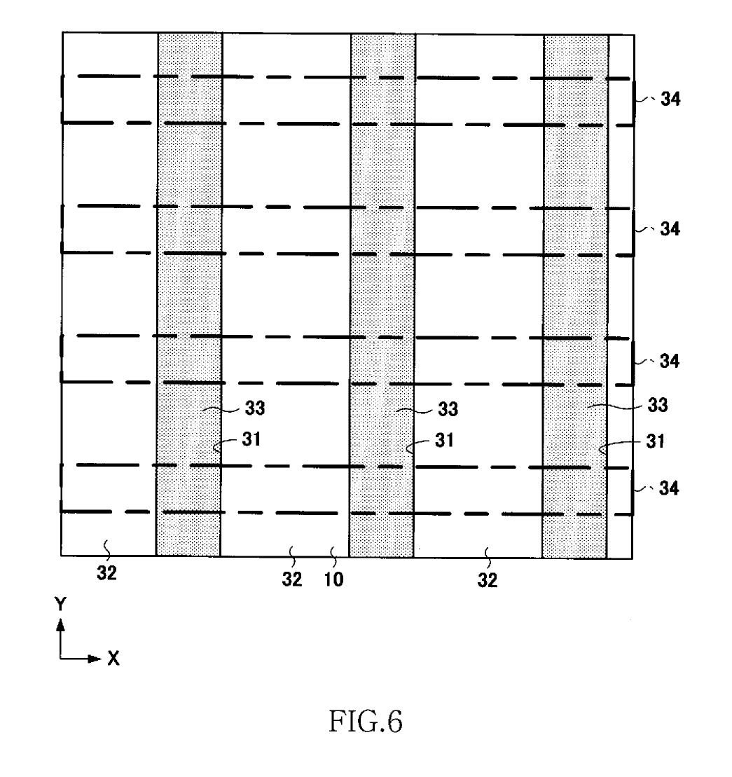

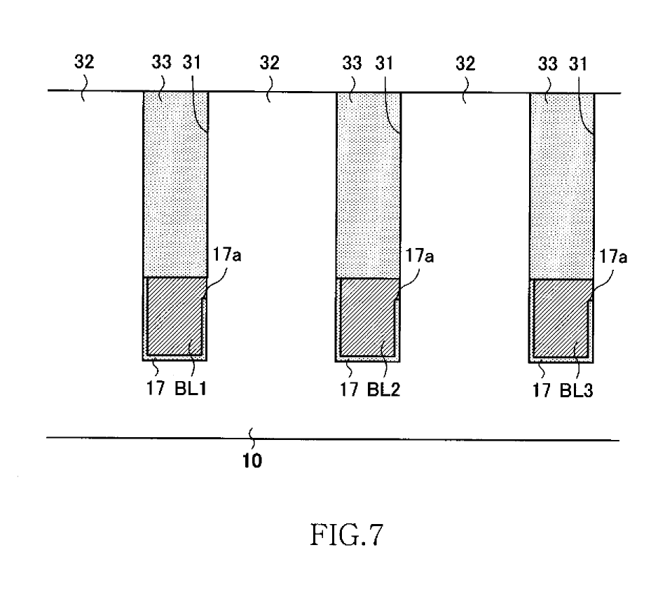

Thereafter, an insulating film 33 of silicon oxide is formed on the top surface of the semiconductor substrate 10, and a CMP (Chemical Mechanical Polishing) is performed with the mask pattern 30 as a stopper, to planarize the top surface. The CMP is performed roughly until the mask pattern 30 is removed. With this process, as shown in FIGS. 6 and 7, the insulating film 33 is embedded in the groove 31.

Next, as shown in FIG. 6, a mask pattern 34 of silicon nitride is formed. In FIG. 6, only the outline of the mask pattern 34 is represented by thick dashed dotted lines. The planar shape of the mask pattern 34 is, as shown in FIG. 6, a line shape extending in the X direction. The width of the mask pattern 34 is slightly narrower than the value of F. For example, if the value of F is 40 nm, it is preferable to set the width of the mask pattern 34 to about 30 nm.

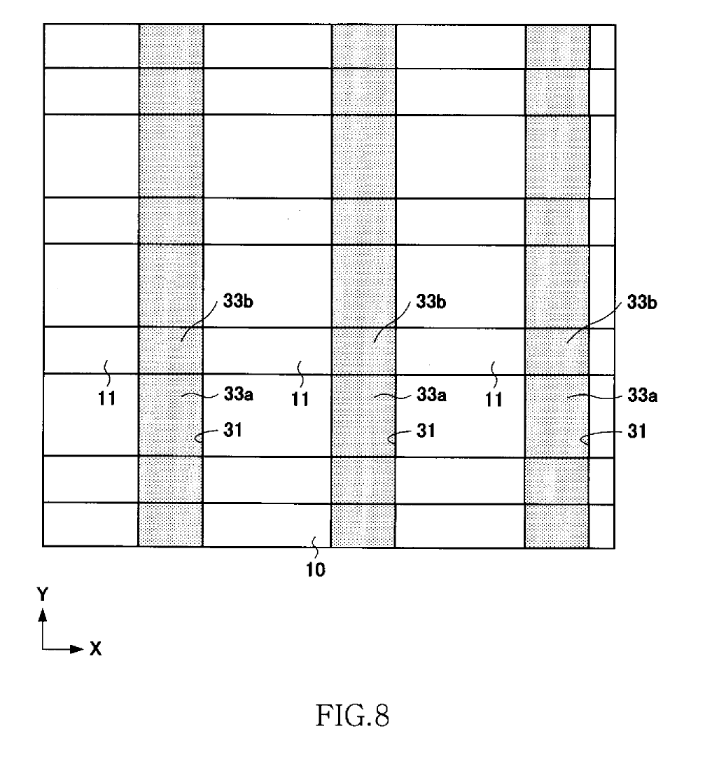

The insulating film 33 of silicon nitride is etched by a depth of 100 nm from the surface of the silicon beam 32, and then the silicon beam 32 is etched by 100 nm. As a result, as shown in FIGS. 8 to 10, the silicon pillar 11 of a rectangular cube of which the planar shape is rectangular with its longitudinal direction parallel to the X direction is formed in a matrix pattern. In FIG. 8, illustration of the mask pattern 34 is omitted. In the insulating film 33, a relatively thin portion 33a having a thickness of about 20 nm and a relatively thick portion 33b having a thickness of about 120 nm are formed.

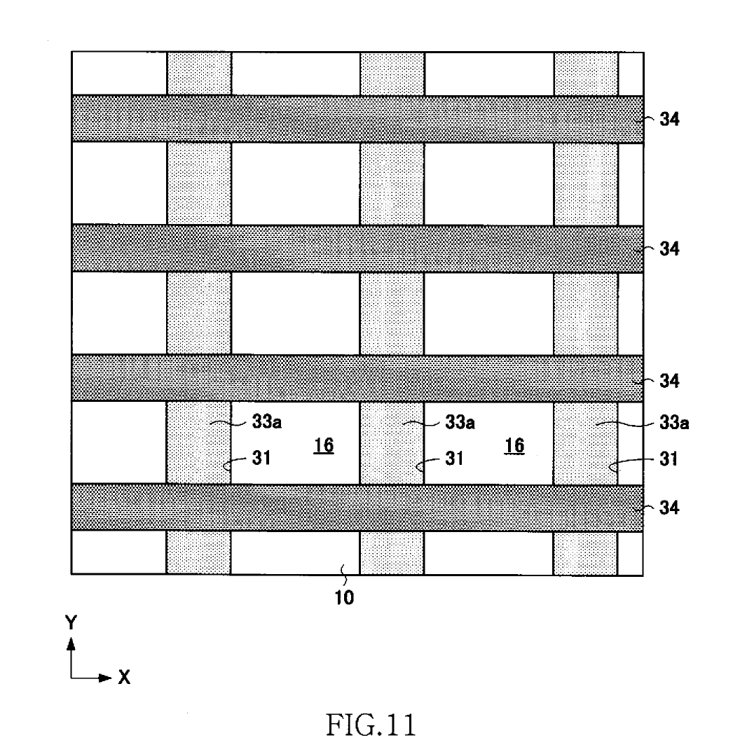

Thereafter, as shown in FIGS. 11 to 13, a silicon oxide layer 35 of a thickness of about 5 nm, which covers the entire top surface, is formed by the CVD (Chemical Vapor Deposition) method. In FIG. 11, illustration of the silicon oxide layer 35 is omitted. The impurity diffusion layer 16 shown in FIGS. 11 to 13 is formed by implanting an impurity such as arsenic from the top of the silicon oxide layer 35. The implantation amount is adjusted such that the impurity diffusion layer 16 is formed right below the silicon pillar 11. For example, it is preferable to implant arsenic of 1×10¹⁵ ions/cm² at 10 KeV by ion implantation. When the implantation of the impurity is complete, the silicon oxide layer 35 is removed.

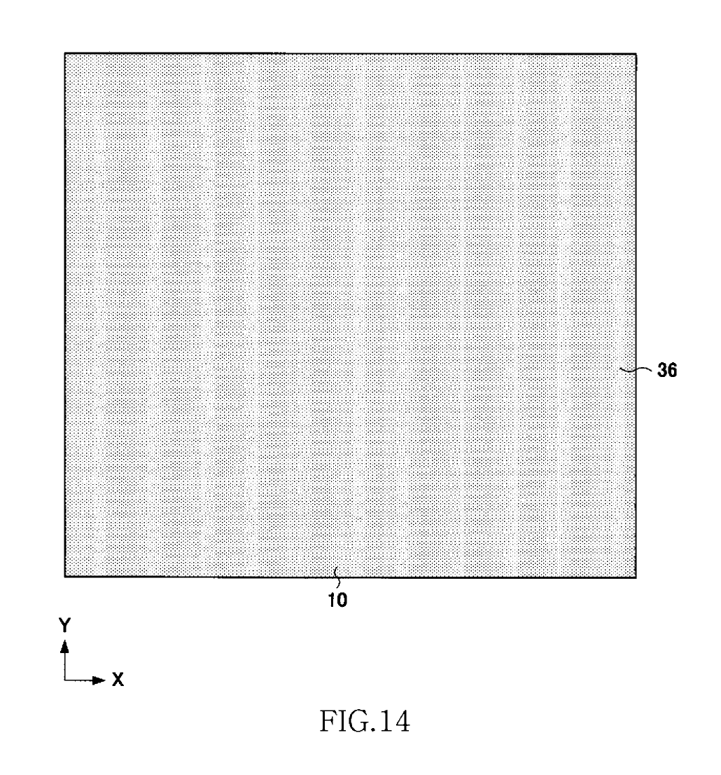

Next, as shown in FIGS. 14 to 16, an insulating film 36 of silicon oxide is formed on the entire top surface. The insulating film 36 is deposited by using the HDPCVD (High Density Plasma Chemical Vapor Deposition) method. By using the HDPCVD method, the insulating film 36 is not formed on the side wall of the silicon pillar 11.

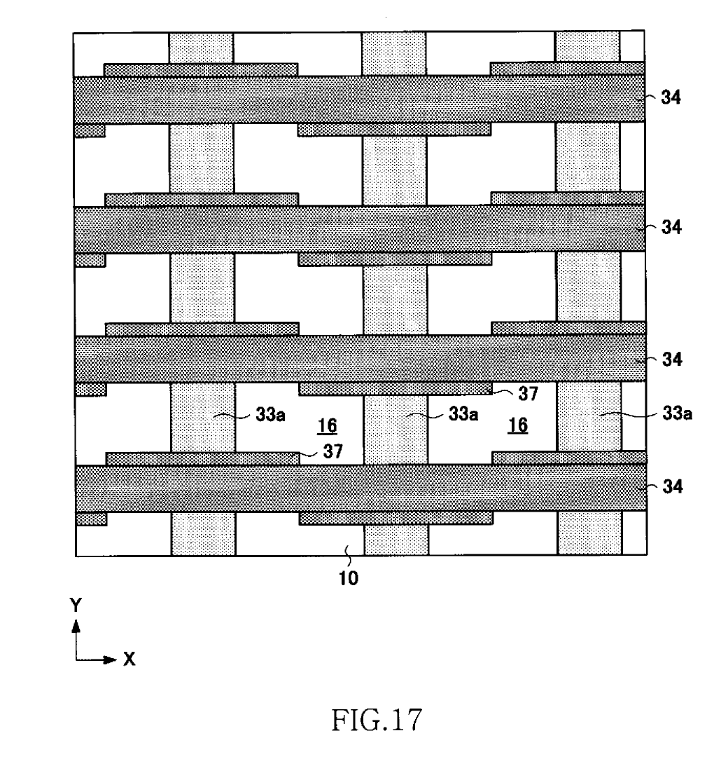

Subsequently, a silicon nitride film of a thickness of about 5 nm, which covers the entire top surface, is formed. A resist mask is formed to cover the areas 13a and 13b (the areas corresponding to the nonoxide areas 11a and 11b) among side surfaces of the silicon pillar 11, an then, the silicon nitride film at an unmasked area is removed by the isotropic vapor etching. As a result, as shown in FIGS. 17 to 19, a silicon nitride film 37 that covers the areas 13a and 13b among the side surfaces of the silicon pillar 11 is formed. In FIG. 17, illustration of the insulating film 36 is omitted. In the present embodiment, as shown in FIG. 17, the silicon nitride film 37 at the side surface is shared between two adjacent silicon pillars 11 via the insulating film 33b (see FIG. 8). The sharing of the silicon nitride film 37 is made possible because the silicon pillars 11 have an opposite structure in the X direction in every other column, as described above.

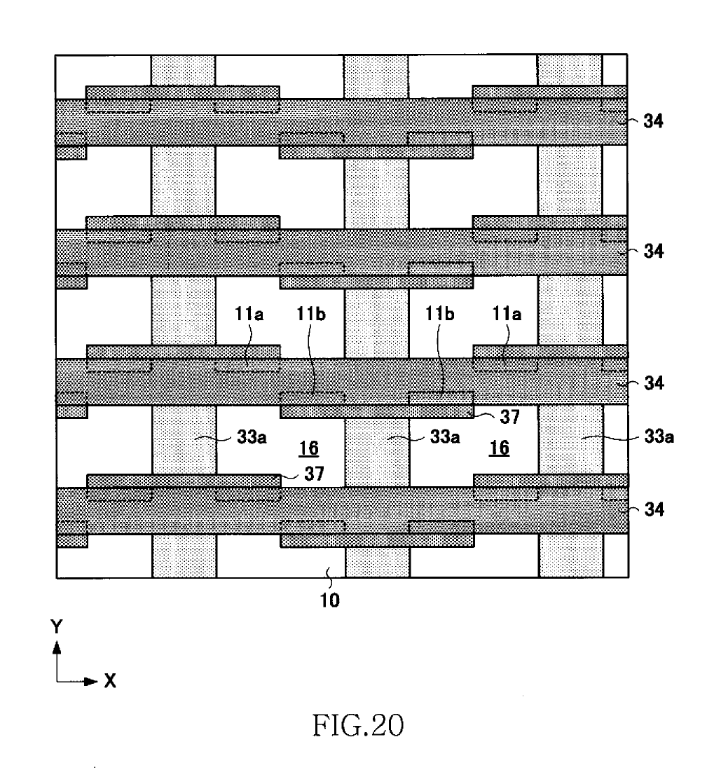

Next, the entire surface is thermally oxidized. By the thermal oxidization, the side surfaces of the silicon pillar 11 where the silicon nitride film 37 is not formed are oxidized, and as shown in FIGS. 20 to 22, the insulating area 11c and the nonoxide areas 11a and 11b that are separated from each other by the insulating area 11c are formed. In FIG. 20, illustration of the insulating film 36 is omitted. In this process, it is necessary to set a condition for the oxidization to about a degree of separating the nonoxide areas 11a and 11b in an insulating manner. For example, it is preferable to select an oxidization condition such that an area of about 20 nm to the inner side of the silicon pillar 11 is oxidized.

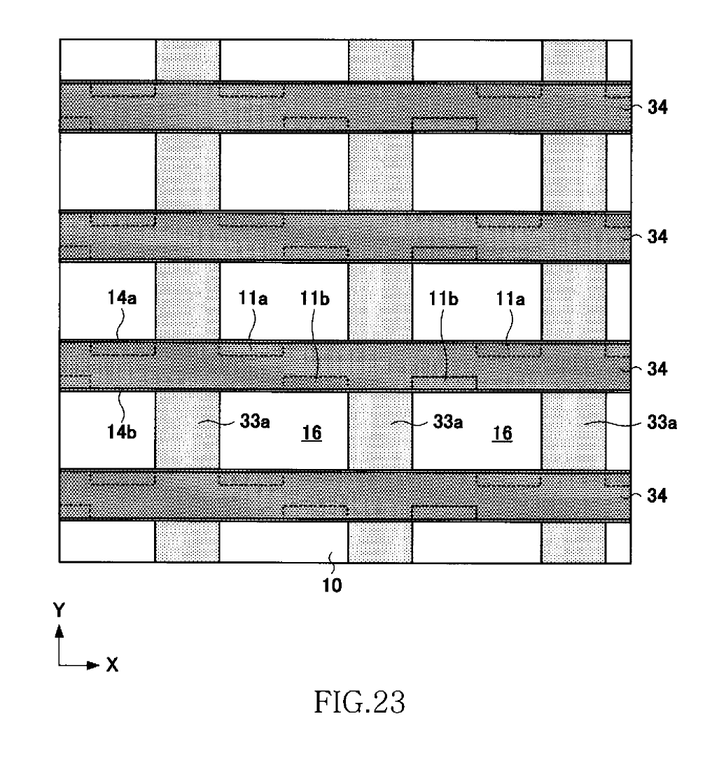

Thereafter, the silicon nitride film 37 is removed by using thermal phosphoric acid, and then, as shown in FIGS. 23 to 25, the gate insulating films 14a and 14b are formed by using the CVD method. In FIG. 23, illustration of the insulating film 36 is omitted. As for the material for the gate insulating films 14a and 14b, it is preferable to use a high permittivity material such as a nitrided hafnium silicate (HfSiON) film. Furthermore, it is preferable to set the thicknesses of the gate insulating films 14a and 14b to 2 nm in silicon oxide film equivalent.

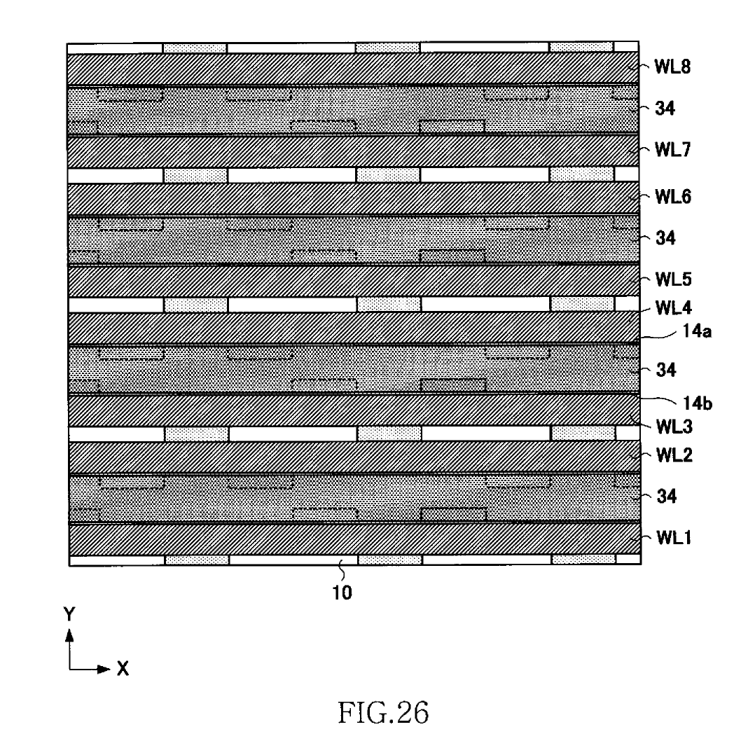

Subsequently, the word line WL is formed along the gate insulating films 14a and 14b, as shown in FIGS. 26 to 28, by depositing a material for the word line WL, such as polysilicon, silicide, metal, or a combination of these materials and performing an etch back. In FIG. 26, illustration of the insulating film 36 is omitted. The height of the word line WL is set to about 80 nm, such that the top of the word line WL is lower than the top of the silicon pillar 11. This is for the top of the word line WL not to be exposed after performing a process of removing the mask pattern 34, as will be described later.

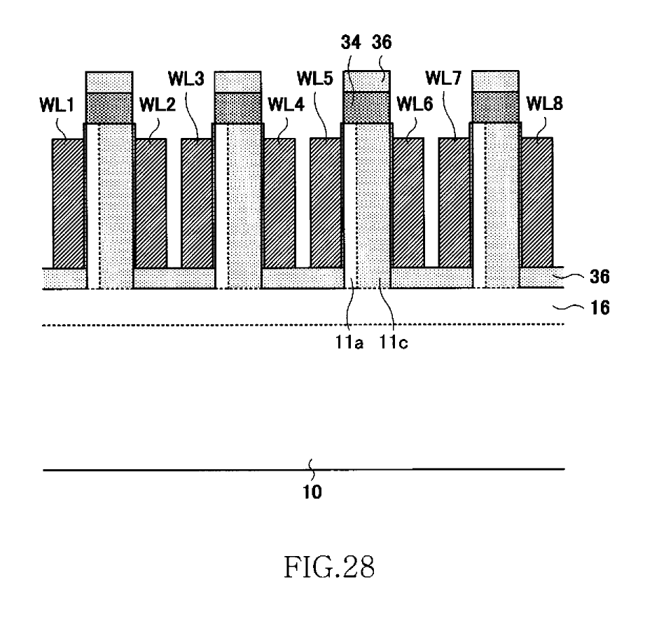

After forming the word line WL, as shown in FIG. 28, the heights of the gate insulating films 14a and 14b are adjusted such that the tops of the gate insulating films 14a and 14b become approximately level with the top of the silicon pillar 11. This adjustment is performed by using the anisotropic dry etching method.

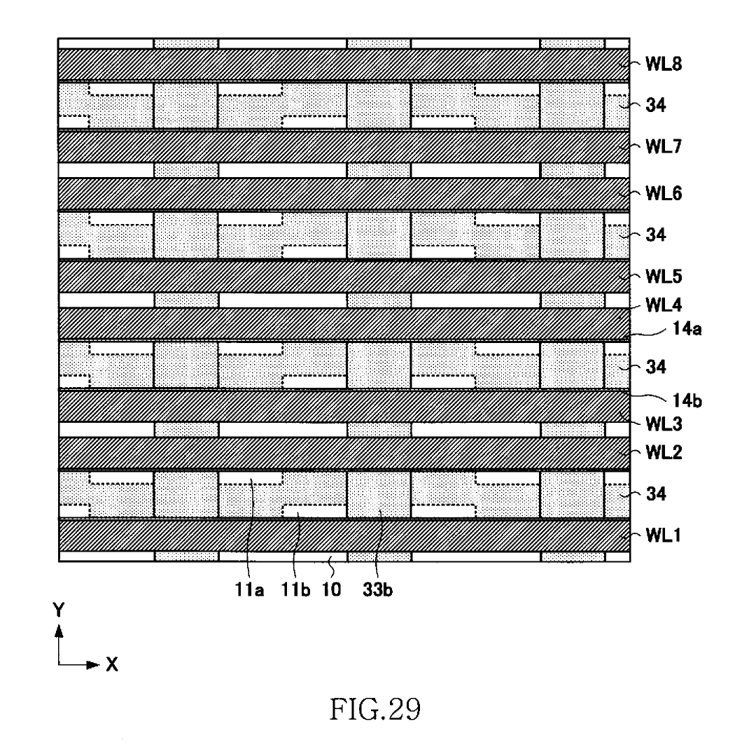

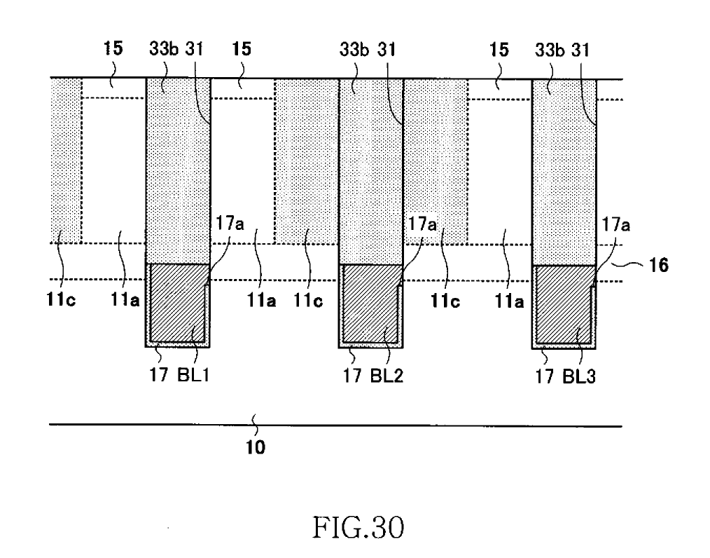

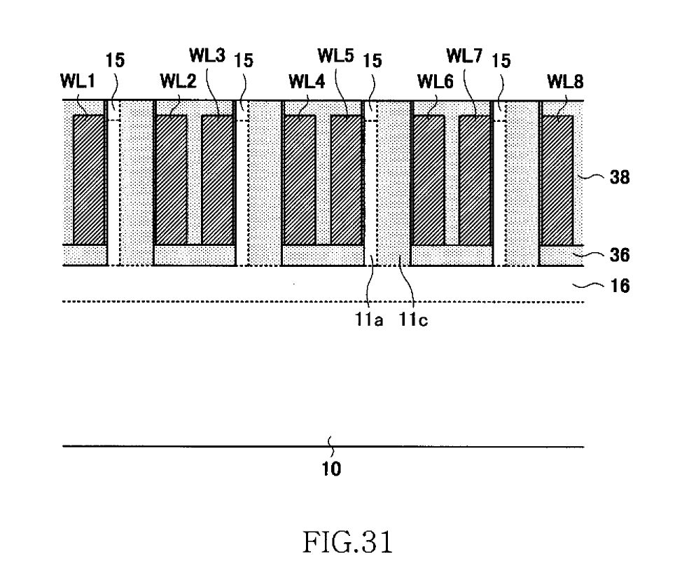

Next, an insulating film 38 of silicon oxide is deposited on the entire top surface, and thereafter, the top surface is planarized by the CMP. The CMP is, as shown in FIGS. 29 to 31, performed approximately until the top of the silicon pillar 11 is exposed. In FIG. 29, illustration of the insulating film 38 is omitted. Subsequently, as shown in FIGS. 30 and 31, the impurity diffusion layer 15 is formed in the top end of each of the nonoxide areas 11a and 11b of the silicon pillar 11 by performing the implantation of arsenic.

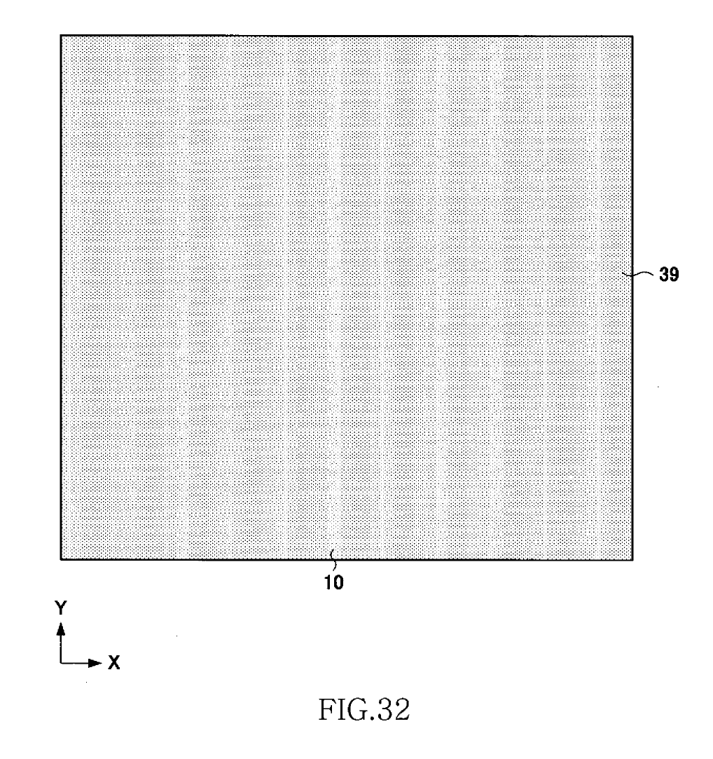

Thereafter, as shown in FIGS. 32 to 34, an inter-layer insulating film 39 of silicon oxide is deposited on the entire top surface. The thickness of the inter-layer insulating film 39 is set to be relatively thick, for example, to about 100 nm. After forming the inter-layer insulating film 39, the surface can be planarized by using the CMP method.

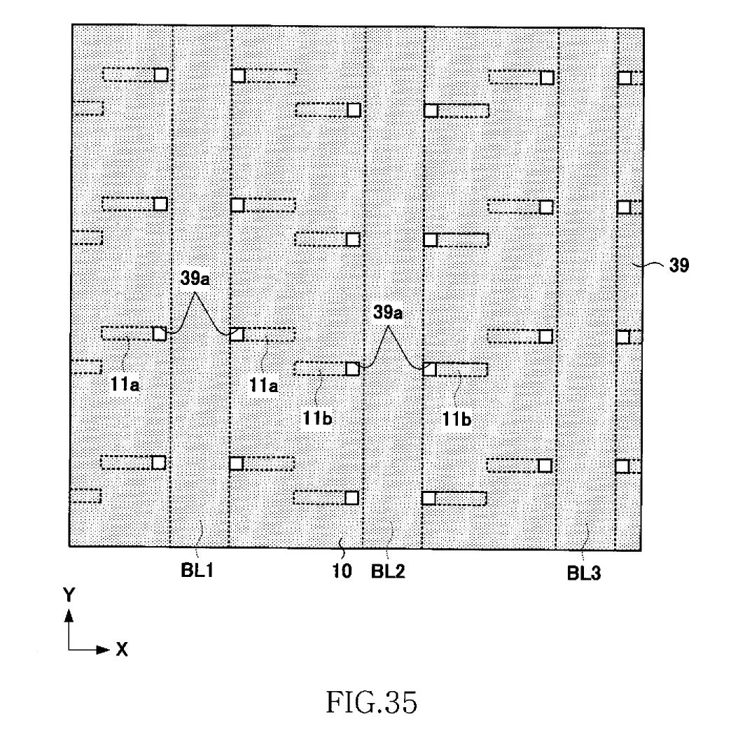

Next, as shown in FIGS. 35 to 37, an opening 39a is formed on the surface of the inter-layer insulating film 39 by forming a resist mask and performing an etching of the inter-layer insulating film 39. The opening 39a is formed at a position in each of the nonoxide areas 11a and 11b close to the bit line BL.

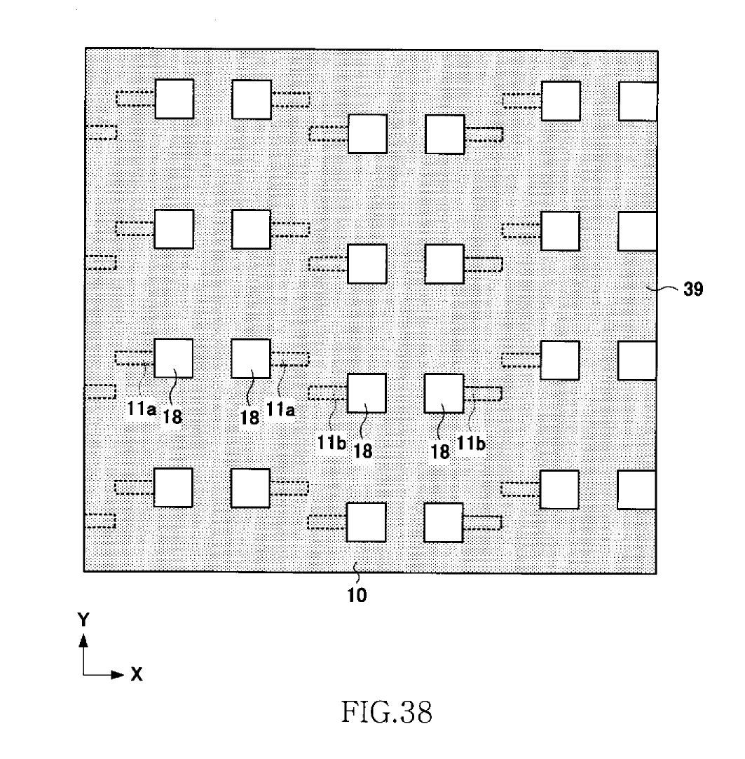

Next, as shown in FIGS. 38 to 40, the memory element contact plug 18 is formed by performing a selective epitaxial growth of silicon in the opening 39a and then a lateral epitaxial growth in a squared shape on a top surface of the inter-layer insulating film 39.

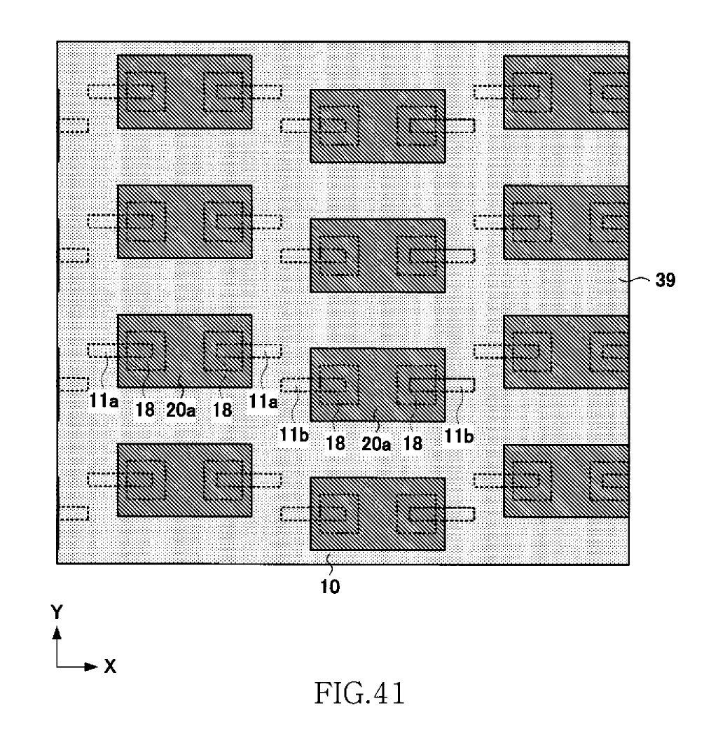

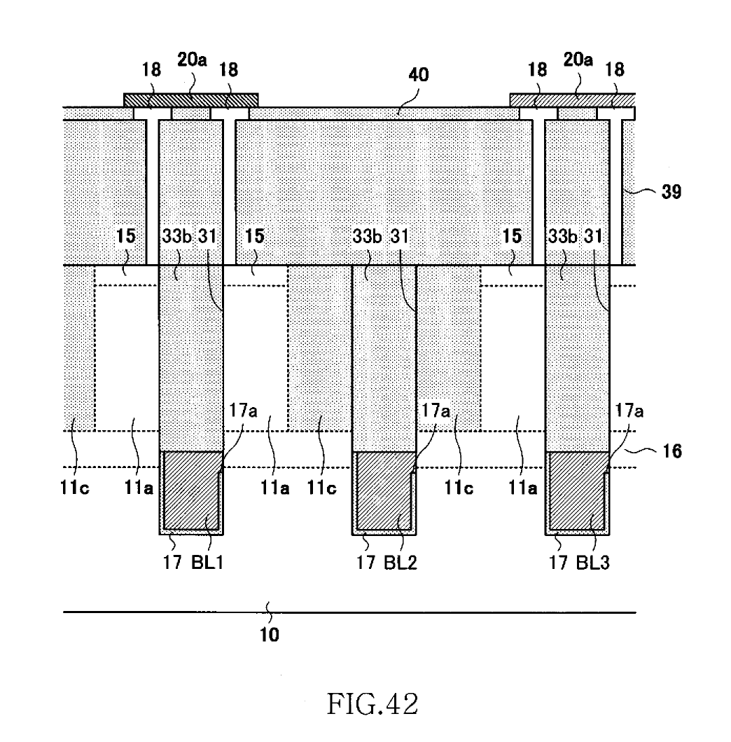

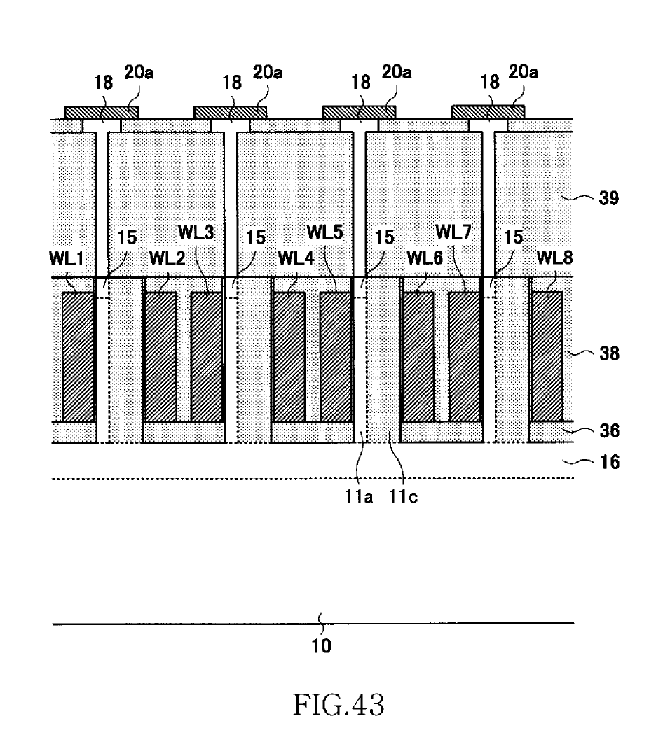

Thereafter, as shown in FIGS. 42 and 43, an inter-layer insulating film 40 is deposited, and the top of the memory element contact plug 18 is exposed by the CMP. As shown in FIGS. 41 to 43, a conductor 20a is formed to cover two adjacent memory element contact plugs 18 across the bit line BL, by depositing a metal film on the top surface and performing a patterning by using a first mask pattern (not shown). The length of the conductor 20a in the X direction is about 2F. The conductor 20a is for forming the lower electrode conductor 20 shown in FIGS. 2 and 3.

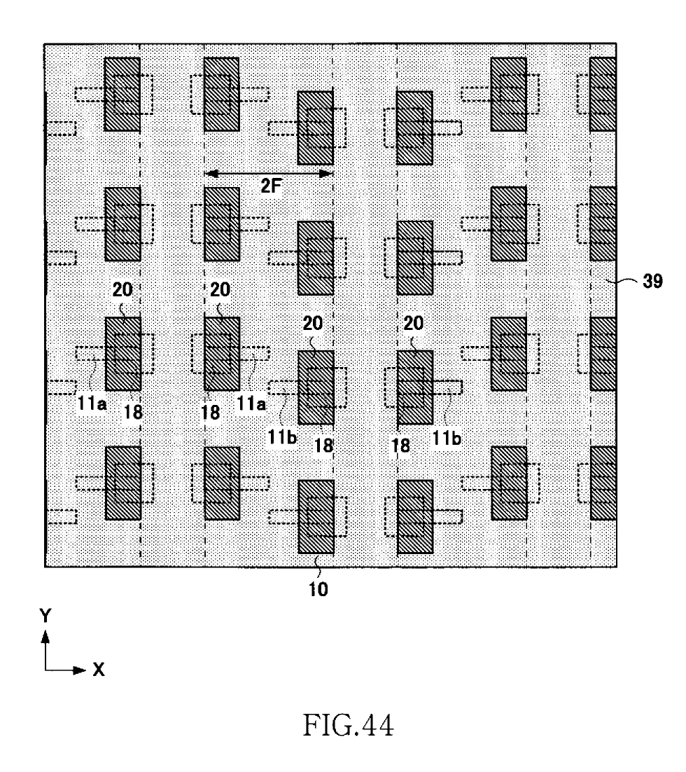

Subsequently, a further patterning is performed on the conductor 20a by using a second mask pattern of which the width in the X direction is 2F, and as shown in FIGS. 44 to 46, the lower electrode conductor 20 is formed for each of the memory element contact plugs 18. In FIG. 44, only the outline of the second mask pattern is shown by dashed dotted lines.

As described above, the lower electrode conductor 20 is formed by using a double patterning method in which two mask patterns are used. Thereafter, as shown in FIGS. 2 and 3, a memory cell is formed by forming the memory element 19 and the reference potential wiring PL on the top layer.

According to the manufacturing method described above, it is possible to manufacture the semiconductor memory device 1 that does not cause any mutual interference between channels and that realizes a layout of 3F².

The present invention is in no way limited to the aforementioned embodiments, but rather various modifications are possible within the scope of the invention as recited in the claims, and naturally these modifications are included within the scope of the invention.

For example, while the P-type semiconductor substrate 10 is used in the above embodiment, it is also possible to use an N-type semiconductor substrate. In this case, the impurity diffusion layers 15 and 16 become P-type.

In addition, while not specifically claimed in the claim section, the applicant reserves the right to include in the claim section of the application at any appropriate time the following methods:

A. A method of manufacturing a semiconductor memory device, comprising:

forming a silicon pillar of which a planar shape is rectangular with its longitudinal direction parallel to an extension direction of a word line;

forming a silicon nitride film that covers first and second areas of the silicon pillar without covering other area, the first area being positioned on one side among two sides parallel to the extension direction of the word line, the second area being positioned on other side among the two sides, the first and second areas being not overlapped in an extension direction of the bit line that is perpendicular to the extension direction of the word line; and

forming an insulating oxide film in the silicon pillar by thermally oxidizing the silicon pillar so as to remain nonoxide areas provided at an inner side of the first area and at an inner side of the second area, the nonoxide areas being electrically isolated from each other by the insulating oxide film.

B. The method as claimed in claim A, further comprising:

forming a first gate insulating film and a second gate insulating film along the two sides, respectively, after

forming the insulating oxide film; and forming a first word line and a second word line that cover the first and second areas via a gate insulating film, respectively.

C. The method as claimed in claim A, further comprising:

forming a contact plug on the silicon pillar by a selective epitaxial growth in a lateral direction; and

forming a lower electrode of a capacitor on the contact plug by using a double patterning method.

What is claimed is:

1. A semiconductor memory device comprising:
a silicon pillar including a first side surface perpendicular to an extension direction of a bit line, a second side surface parallel to the first side surface, a first channel region positioned on the first side surface, a second channel region positioned on the second side surface, and an oxide region that electrically isolates the first and second channel regions; and
first and second word lines that cover the first and second side surfaces via gate insulating films, respectively,
wherein the first and second channel regions being not overlapped in the extension direction of the bit line.

2. The semiconductor memory device as claimed in claim 1, wherein channel widths of the first channel region and the second channel region are minimum feature size F.

3. The semiconductor memory device as claimed in claim 1, wherein the silicon pillar further includes a first diffusion region on an upper portion of each of the first and second channel regions.

4. The semiconductor memory device as claimed in claim 1, further comprising a base silicon layer provided below the silicon pillar,
wherein the base silicon layer including a second diffusion region electrically connected to the first and second channel regions.

5. The semiconductor memory device as claimed in claim 1, wherein the silicon pillar is provided in plural in a matrix form.

6. A semiconductor memory device comprising a silicon pillar of a rectangular cube made of silicon and insulator,
wherein the silicon pillar includes first and second channel regions that serve as channels of first and second vertical MOS transistors having a common lower diffusion layer, respectively,
the first and second channel regions are provided at diagonal positions of the silicon pillar, and
the first channel region and the second channel region are electrically isolated from each other by the insulator in the silicon pillar.

7. The semiconductor memory device as claimed in claim 6, further comprising two gate electrodes that control the two vertical MOS transistors, respectively,
wherein the two gate electrodes are arranged opposite to each other across the silicon pillar.

8. The semiconductor memory device as claimed in claim 6, wherein channel widths of the first channel and the second channel are minimum feature size F.

9. The semiconductor memory device as claimed in claim 6, wherein the silicon pillar is provided in plural in a matrix form.
